(19) United States
(12) Patent Application Publication
(10) Pub. No.: US 2026/0256007 A1
(43) Pub. Date: Aug. 27, 2026

(54) SEMICONDUCTOR PACKAGE

(71) Applicant: ELECTRONICS AND TELECOMMUNICATIONS RESEARCH INSTITUTE, Daejeon (KR)

(72) Inventor: Hyun-cheol BAE, Daejeon (KR)

(21) Appl. No.: 19/380,423

(22) Filed: Nov. 5, 2025

(30) Foreign Application Priority Data
Feb. 27, 2025 (KR) 10-2025-0025690

(51) Int. Cl. H10W 72/50; H10W 72/00; H10W 72/30; H10W 90/00

(52) U.S. Cl. CPC H10W 72/50; H10W 72/851; H10W 72/01338; H10W 72/073; H10W 72/07332; H10W 72/352; H10W 90/734

(57) ABSTRACT

A semiconductor package includes a semiconductor substrate including an upper surface and a lower surface opposite to each other; a semiconductor chip disposed on the upper surface of the semiconductor substrate and including first and second surfaces opposite to each other; and a silver adhesive layer interposed between the semiconductor substrate and the semiconductor chip, wherein the silver adhesive layer is in contact with the upper surface of the semiconductor substrate and the first surface of the semiconductor chip, and the upper surface of the semiconductor substrate and the first surface of the semiconductor chip face each other, wherein the semiconductor chip includes a wide band gap semiconductor chip, wherein a thickness of the silver adhesive layer in a third direction is in a range of 3μm to 10μm, and the third direction is a direction perpendicular to the upper surface of the semiconductor substrate.

### CROSS-REFERENCE TO RELATED APPLICATION(S)

This U.S. non-provisional patent application claims priority under 35 U.S.C. §119 to Korean Patent Application No. 10-2025-0025690, filed on February 27, 2025, in the Korean Intellectual Property Office, the entire contents of which are hereby incorporated by reference.

### BACKGROUND OF THE INVENTION

### Field of the Invention

The inventive concept relates to a semiconductor package, and more particularly, to the semiconductor package including a silver adhesive layer.

### Description of Related Art

In the case of power semiconductors, a high heat dissipation capability is required on the package side. Accordingly, a silver sintering bonding material having high thermal conductivity is widely used. At this time, the thermal conductivity of the bonding material is low, and a problem of lowering the heat dissipation characteristics of the semiconductor package occurs.

Furthermore, when the bonding material is used, many processes such as a printing process, an alignment process, and a bonding process are required. Accordingly, there is a problem that a defect occurs when the process conditions are not secured.

In addition, when the bonding material is used, a phenomenon in which the bonding material is re-melted due to high heat generation of the power semiconductor occurs, and the reliability of the semiconductor package may be deteriorated.

### SUMMARY

An embodiment of the inventive concept provides a semiconductor package with improved reliability.

According to an embodiment of the inventive concept, a semiconductor package may comprise a semiconductor substrate including an upper surface and a lower surface opposite to each other; a semiconductor chip disposed on the upper surface of the semiconductor substrate and including a first surface and a second surface opposite to each other; and a silver adhesive layer interposed between the semiconductor substrate and the semiconductor chip, wherein the silver adhesive layer is in contact with the upper surface of the semiconductor substrate and the first surface of the semiconductor chip, wherein the upper surface of the semiconductor substrate and the first surface of the semiconductor chip face each other, wherein the semiconductor chip includes a wide band gap semiconductor chip, wherein a thickness of the silver adhesive layer in a third direction is in a range of 3μm to 10μm, and the third direction is a direction perpendicular to the upper surface of the semiconductor substrate.

According to an embodiment of the inventive concept, a manufacturing a semiconductor package may comprise, forming a first silver adhesive layer on a upper surface of a semiconductor substrate; forming a second silver adhesive layer on a first surface of the semiconductor chip; disposing the first surface of the semiconductor chip to face the upper surface of the semiconductor substrate; and thermocompression bonding the semiconductor substrate and the semiconductor chip, wherein the semiconductor chip includes a wide band gap semiconductor chip, and forming the first silver adhesive layer and the second silver adhesive layer comprises a sputtering step.

### BRIEF DESCRIPTION OF THE DRAWINGS

FIG. 1 is a top view of a semiconductor package according to embodiments of the inventive concept.

FIG. 2 is a cross-sectional view according to A-A′ of FIG. 1.

FIGS. 3-5 are views illustrating a method of manufacturing a semiconductor package according to embodiments of the inventive concept.

### DETAILED DESCRIPTION

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to an embodiment” (or other phrases having a similar meaning) in various places throughout this specification are not necessarily all referring to the same embodiment. Furthermore, the particular features, structures, or characteristics may be combined in any suitable manner in one or more embodiments. In this regard, as used herein, the word “exemplary” means “provides an example, illustration, or illustration.” Any embodiment described herein as “exemplary” is not necessarily to be construed as preferred or advantageous over other embodiments. Also, depending on the context of the discussion herein, the singular may include the corresponding plural forms and the plural terms may include the corresponding singular forms. It should be noted that the various figures(including block diagrams) shown and discussed herein are for illustrative purposes only and are not drawn to scale.

Hereinafter, the inventive concept will be described in detail by explaining embodiments of the inventive concept with reference to the accompanying drawings.

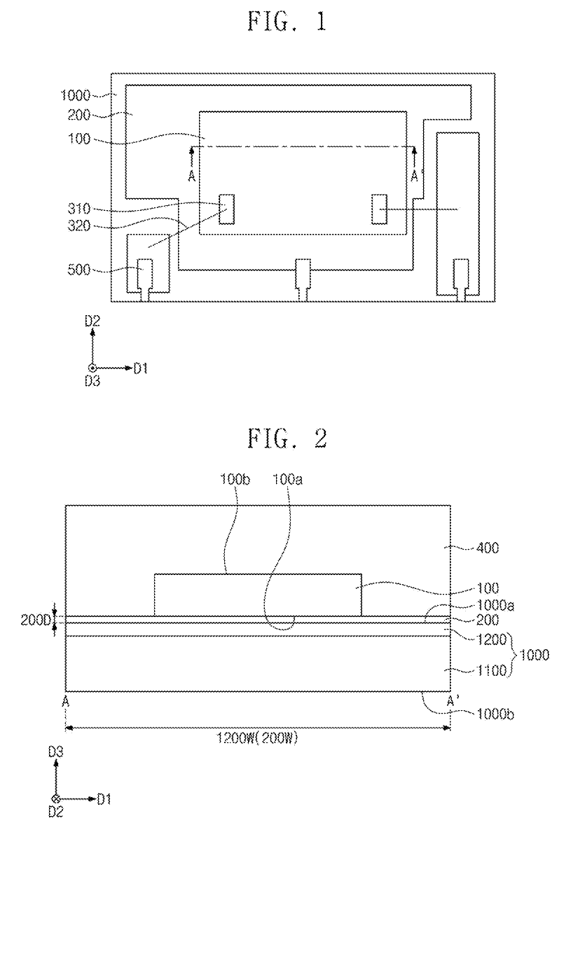

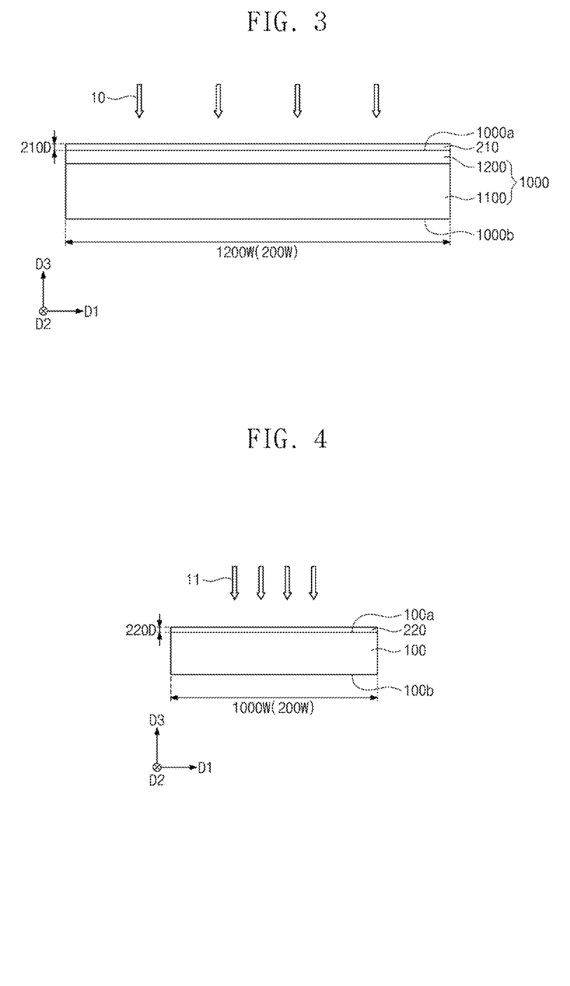

FIG. 1 is a top view of a semiconductor package according to embodiments of the inventive concept. FIG. 2 is a cross-sectional view according to A-A′ of FIG. 1.

Referring to FIGS. 1 and 2, a semiconductor substrate 1000 including an upper surface 1000a and a lower surface 1000b opposite to each other may be provided. The semiconductor substrate 1000 may be, for example, a ceramic substrate. The semiconductor substrate 1000 may include a ceramic layer 1100, and metal patterns 1200 disposed on the ceramic layer 1100. The ceramic layer 1100 may include, for example, any one or more selected from the group consisting of aluminum oxide, aluminum nitride, silicon nitride, and combinations thereof.

The semiconductor chip 100 may be disposed on the upper surface 1000a of the semiconductor substrate 1000. The semiconductor chip 100 may include a first surface 100a and a second surface 100b opposite to each other. The first surface 100a of the semiconductor chip 100 may face the upper surface 1000a of the semiconductor substrate 1000.

Connection pads 310 may be disposed on the second surface 100b of the semiconductor chip 100. The connection pads 310 may be electrically connected to the metal patterns 1200 of the semiconductor substrate 1000 through bonding wires 320 described below. The metal patterns 1200 of the semiconductor chip 100 and the semiconductor substrate 1000 may be electrically connected to each other through the connection pads 310.

The semiconductor chip 100 may include a power semiconductor chip, for example, and may include a transistor, for example. The semiconductor chip 100 may include a wide band gap semiconductor chip, for example, and may include any one or more selected from the group consisting of SiC, GaN, and compounds thereof, for example.

A silver adhesive layer 200 may be interposed between the semiconductor substrate 1000 and the semiconductor chip 100. The silver adhesive layer 200 may contact the upper surface 1000a of the semiconductor substrate 1000 and may contact the first surface 100a of the semiconductor chip 100. The silver adhesive layer 200 may be formed on a corresponding one of the metal patterns 1200 of the semiconductor substrate 1000. The silver adhesive layer 200 may be uniformly formed on the corresponding metal pattern. A width 200W of the silver adhesive layer 200 in a first direction D1 may be the same as a width 1200W of the corresponding metal pattern in the first directionD1.

In the present specification, the first direction D1 may be a direction parallel to the upper surface 1000a of the semiconductor substrate 1000. A second direction D2 may be a direction parallel to the upper surface 1000a of the semiconductor substrate 1000 and intersecting the first direction D1. A third direction may be a direction perpendicular to the upper surface 1000a of the semiconductor substrate 1000.

The silver adhesive layer 200 may be composed of silver (Ag) nanoparticles. The silver adhesive layer 200 may include only silver nanoparticles, for example. The silver adhesive layer 200 may be formed through a sputtering process to be described later. A thickness 200D of the silver adhesive layer 200 in the third direction D3 may be in a range of 3μm to 10μm. The thickness 200D of the silver adhesive layer 200 in the third direction D3 may be in a range of 3μm to 5μm.

When the thickness 200D of the silver adhesive layer 200 in the third direction D3 is less than 3μm, a bonding force between the semiconductor substrate 1000 and the semiconductor chip 100 is weak, and thus the mechanical rigidity of the semiconductor package may be reduced. When the thickness 200D of the silver adhesive layer 200 in the third direction D3 is greater than 10μm, the silver adhesive layer 200 may not be uniformly deposited on the semiconductor substrate 1000 and the semiconductor chip 100. Furthermore, since the thickness 200D of the silver adhesive layer 200 in the third direction D3 is large, the heat dissipation efficiency may be reduced.

According to embodiments of the inventive concept, the silver adhesive layer 200 may be composed of silver nanoparticles and may be formed in a thin thickness. The silver (Ag) nanoparticles have high thermal conductivity, so that heat of the semiconductor chip 100 can be easily released. Thus, the reliability of the semiconductor package can be improved.

Further, since the sintered paste, the adhesive, and the like are not contained, a failure in melting the sintering paste, the adhesive and the like again due to heat generated in the semiconductor chip 100 may not occur. In addition, the silver nanoparticles may be formed to have a small thickness to improve the degree of integration of the semiconductor package.

The bonding wires 320 may electrically connect the metal patterns 1200 of the semiconductor substrate 1000 and the connection pads 310 of the semiconductor chip 100. The bonding wires 320 may include, for example, at least one selected from the group consisting of copper, gold, aluminum, and alloys thereof.

Lead structures 500 may be disposed on the upper surface 1000a of the semiconductor substrate 1000. The lead structures 500 may be electrically connected with the metal patterns 1200 of the semiconductor substrate 1000. Each of the lead structures 500 may electrically connect the semiconductor package with an external circuit, as an example. Each of the lead structures 500 may include, for example, any one or more selected from the group consisting of copper, iron, nickel, silver, gold, and alloys thereof.

A molding layer 400 may be disposed on the upper surface 1000a of the semiconductor substrate 1000. The molding layer 400 may cover the upper surface 1000a of the semiconductor substrate 1000, the semiconductor chip 100, the bonding wires 320, and the silver adhesive layer 200. The molding layer 400 can protect the semiconductor package from external impact. The molding layer 400 may include, for example, an epoxy molding compound.

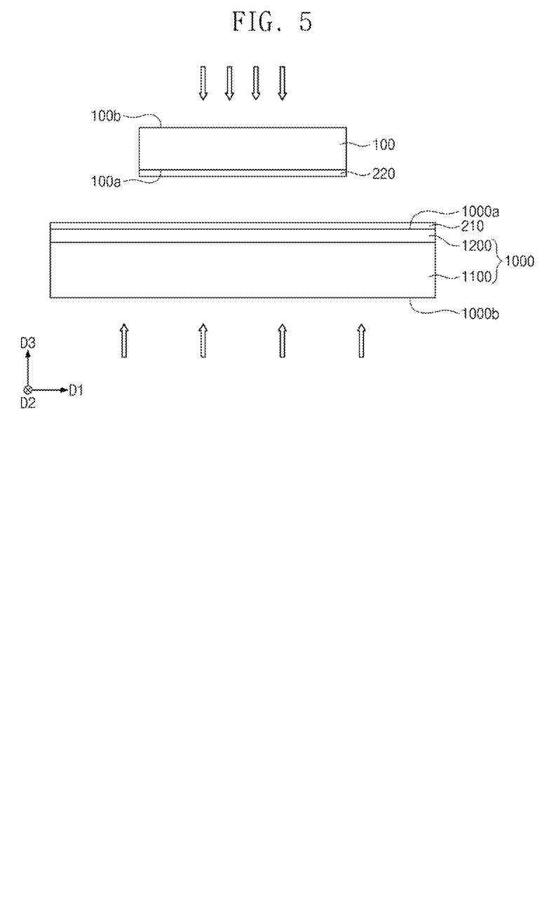

FIGS. 3-5 are views illustrating a method of manufacturing a semiconductor package according to embodiments of the present invention. FIGS. 3-5 are cross-sectional views corresponding to A-A′ of FIG. 1. For simplicity of description, description overlapping with the semiconductor package described with reference to FIGS. 1 and 2 is omitted.

Referring to FIG. 3, the semiconductor substrate 1000 including the upper surface 1000a and the lower surface 1000b opposite to each other may be provided. The semiconductor substrate 1000 may include the ceramic layer 1100, and the metal patterns 1200 disposed on the ceramic layer 1100.

A first silver adhesive layer 210 may be formed on the upper surface 1000a of the semiconductor substrate 1000. The first silver adhesive layer 210 may be composed of silver nanoparticles. That is, the first silver adhesive layer 210 may include only silver nanoparticles. The first silver adhesive layer 210 may be formed on a corresponding one of the metal patterns 1200 of the semiconductor substrate 1000. The first silver adhesive layer 210 may be uniformly formed on the corresponding metal pattern. A width 210W of the first silver adhesive layer 210 in the first direction D1 may be the same as the width 1200W of the corresponding metal pattern in the first directionD1.

A thickness 210D of the first silver adhesive layer 210 in the third direction D3 may be 10μm or less. The thickness 210D of the first silver adhesive layer 210 in the third direction D3 may be in a range of 3μm to 5μm. Forming the first silver adhesion layer 210 may include, for example, depositing silver nanoparticles through the sputtering process 10.

Referring to FIG. 4, the semiconductor chip 100 including the first surface 100a and the second surface 100b opposite to each other may be provided. A second silver adhesive layer 220 may be formed on the first surface 100a of the semiconductor chip 100. The second silver adhesive layer 220 may be composed of silver nanoparticles. That is, the second silver adhesive layer 220 may include only silver nanoparticles.

The second silver adhesive layer 220 may be uniformly formed on the upper surface 1000a of the semiconductor substrate 1000. A width 220W of the second silver adhesive layer 220 in the first direction D1 may be the same as a width 100W of the semiconductor chip 100 in the first directionD1. A thickness 220D of the second silver adhesive layer 220 in the third direction D3 may be 10μm or less. The thickness 220D of the second silver adhesive layer 220 in the third direction D3 may be 3μm to 5μm. Forming the second silver adhesive layer 220 may include, for example, depositing silver nanoparticles via a sputtering process 11.

Referring to FIG. 5, the first surface 100a of the semiconductor chip 100 may be disposed to face the upper surface 1000a of the semiconductor substrate 1000. The second silver adhesive layer 200 on the first surface 100a of the semiconductor chip 100 may be disposed to face the first silver adhesive layer 210 on the upper surface 1000a of the semiconductor substrate 1000.

Thereafter, a thermocompression bonding process 12 may proceed. Through the thermocompression bonding process, the first silver adhesive layer 210 and the second silver adhesive layer 220 may be integrated, whereby the silver adhesive layer 200 may be formed. The thermocompression process may proceed, for example, with a pressure of 0.1Mpa to 20Mpa. The thermocompression process may, for example, proceed at a pressure of 0.1Mpa to 10Mpa. The thermocompression process may, for example, proceed at a temperature of 150° C. to 400° C.

According to embodiments of the inventive concept, the first and second silver adhesive layers 210, 220 may be formed via sputtering. The first and second silver adhesive layers 210, 220 may be bonded to each other in the thermocompression process.

That is, according to embodiments of the inventive concept, a printing process, an alignment process, a bonding process, or the like may be omitted because a paste, an adhesive, or the like is not used. Therefore, a manufacturing process of the semiconductor package can be simplified, and a method for manufacturing the semiconductor package in which time and cost required for the manufacturing process are reduced can be provided.

Referring again to FIGS. 1 and 2, the bonding wires 320 may be formed. The bonding wires 320 may electrically connect the metal patterns 1200 of the semiconductor substrate 1000 with the connection pads 310 of the semiconductor chip 100. Forming the bonding wires 320 may include, for example, a capillary process.

The molding layer 400 may be formed on the upper surface 1000a of the semiconductor substrate 1000. The lead structures 500 may then be formed on the upper surface 1000a of the semiconductor substrate 1000. The lead structures 500 may be electrically connected with the metal patterns 1200 of the semiconductor substrate 1000. Forming the lead structures 500 may include, for example, plating a metal material and patterning the metal material.

According to embodiments of the inventive concept, the silver adhesive layer 200 may be interposed between the semiconductor substrate 1000 and the semiconductor chip 100. The silver adhesive layer 200 may be composed of silver nanoparticles and may be formed by a sputtering process. The silver adhesive layer 200 is composed of silver nanoparticles, and may have a thin thickness, and may have excellent high thermal conductivity. Thus, heat generated in the semiconductor chip 100 may be easily released. Accordingly, a semiconductor package with improved reliability may be provided.

Furthermore, the silver adhesive layer 200 may be deposited uniformly on the semiconductor substrate 1000 and the semiconductor chip 100 in a sputtering process. Thereafter, the semiconductor substrate 1000 and the semiconductor chip 100 may be bonded through a thermocompression bonding process. That is, the bonding process between the semiconductor substrate and the semiconductor chip may be simplified, and the time and cost required for the bonding process may be reduced.

Although the embodiments of the inventive concept have been described above with reference to the accompanying drawings, it will be understood that those skilled in the art can make various modifications and changes to the present invention without departing from the spirit and scope of the present invention as set forth in the following claims. Note that the embodiments disclosed in the present invention are not intended to limit the technical idea of the present invention, and all technical ideas falling within the scope of the following claims and equivalents thereof should be construed as being included in the scope of the present invention.

What is claimed is:

1. A semiconductor package comprising:
a semiconductor substrate including an upper surface and a lower surface opposite to each other;
a semiconductor chip disposed on the upper surface of the semiconductor substrate and including a first surface and a second surface opposite to each other; and
a silver adhesive layer interposed between the semiconductor substrate and the semiconductor chip,
wherein the silver adhesive layer is in contact with the upper surface of the semiconductor substrate and the first surface of the semiconductor chip,
wherein the upper surface of the semiconductor substrate and the first surface of the semiconductor chip face each other,
wherein the semiconductor chip includes a wide band gap semiconductor chip,
wherein a thickness of the silver adhesive layer in a third direction is in a range of 3 μm to 10 μm, and
the third direction is a direction perpendicular to the upper surface of the semiconductor substrate.

2. The semiconductor package of claim 1, wherein the silver adhesive layer is composed of silver (Ag) nanoparticles.

3. The semiconductor package of claim 1, wherein the semiconductor substrate further comprises:
a ceramic layer; and
metal patterns disposed on the ceramic layer.

4. The semiconductor package of claim 3, further comprising lead structures disposed on the upper surface of the semiconductor substrate and electrically connected with the metal patterns.

5. The semiconductor package of claim 3, further comprising bonding wires electrically connecting the semiconductor chip and the metal patterns.

6. The semiconductor package of claim 3, wherein the silver adhesive layer is disposed on a corresponding one of the metal patterns,
a width of the silver adhesive layer in a first direction is the same as a width of the metal pattern in the first direction, and
the first direction is a direction parallel to an upper surface of the semiconductor substrate.

7. The semiconductor package of claim 1, wherein a thickness of the silver adhesive layer in the third direction is in a range of 3μm to 5μm.

8. The semiconductor package of claim 1, further comprising:
a molding layer covering the upper surface of the semiconductor substrate and the semiconductor chip.

9. The semiconductor package of claim 1, wherein the semiconductor chip comprises any one or more selected from the group consisting of SiC, GaN, and compounds thereof.

10. A method for semiconductor package, comprising:
forming a first silver adhesive layer on a upper surface of a semiconductor substrate;
forming a second silver adhesive layer on a first surface of the semiconductor chip;
disposing the first surface of the semiconductor chip to face the upper surface of the semiconductor substrate; and
thermocompression bonding the semiconductor substrate and the semiconductor chip,
wherein the semiconductor chip includes a wide band gap semiconductor chip, and
forming the first silver adhesive layer and the second silver adhesive layer comprises a sputtering step.

11. The method for semiconductor package of claim 10, wherein the first silver adhesive layer and the second silver adhesive layer are composed of silver nanoparticles.

12. The method for semiconductor package of claim 10, wherein a thickness of the first silver adhesive layer in the third direction is in a range of 3μm to 10μm, and
the third direction is a direction perpendicular to the upper surface of the semiconductor substrate.

13. The method for semiconductor package of claim 10, wherein a thickness of the second silver adhesive layer in the third direction is in a range of 3μm to 10μm, and
the third direction is a direction perpendicular to the upper surface of the semiconductor substrate.

14. The method for semiconductor package of claim 10, wherein a width of the second silver adhesive layer in a first direction is equal to a width of the semiconductor chip in the first direction, and
the first direction is a direction parallel to an upper surface of the semiconductor substrate.

15. The method for semiconductor package of claim 10, wherein the first silver adhesive layer and the second silver adhesive layer are integrally formed through the thermocompression bonding.
